(19) United States
(12) Patent Application Publication
(10) Pub. No.: US 2024/0281202 A1
(43) Pub. Date: Aug. 22, 2024

(54) Electronic Device Audio Adjustment

(71) Applicant: Hewlett-Packard Development Company, L.P., Spring, TX (US)

(72) Inventors: Alexander Morgan Williams, Spring, TX (US); Anthony Nicholas Kaplanis, Spring, TX (US); Raymond James Rolston, Spring, TX (US)

(21) Appl. No.: 18/571,521

(22) PCT Filed: Jun. 25, 2021
(86) PCT No.: PCT/US2021/039210

§ 371 Date: Dec. 18, 2023

(51) Int. Cl. G06F 3/16; H04R 3/00

(52) U.S. Cl. CPC G06F 3/165; G06F 3/162; H04R 3/00; H04R 2420/07; H04R 2430/01

(57) ABSTRACT

In some examples, a method includes establishing a wireless connection between a source electronic device and an audio output device. In some examples, the method includes using a user audio preference and audio output information to determine an audio adjustment. In some examples, the method includes adjusting a volume of the audio output device based on the determined audio adjustment.

### BACKGROUND

The use of electronic devices has expanded. Some electronic devices include electronic circuitry for performing processing. As processing capabilities have expanded, electronic devices have been utilized to perform more functions. For example, a variety of electronic devices are used for work, communication, and entertainment. Electronic devices may be linked to other devices and may communicate with other devices.

### BRIEF DESCRIPTION OF THE DRAWINGS

FIG. 1 is a block diagram illustrating an example of an electronic device for electronic device audio adjustment;

FIG. 2 is a block diagram illustrating an example of an apparatus for electronic device audio adjustment;

FIG. 3 is a block diagram illustrating an example of an electronic device for electronic device audio adjustment;

FIG. 4 is a flow diagram illustrating an example of a method for electronic device audio adjustment;

FIG. 5 is a flow diagram illustrating an example of a method for electronic device audio adjustment; and

FIG. 6 is a block diagram illustrating an example of a computer-readable medium for electronic device audio adjustment.

### DETAILED DESCRIPTION

Today when speakers are being used, users may frequently adjust their volume controls for overall sound output and spikes in audio that may occur. Furthermore, when users switch devices, the listening experience may change because of device capabilities, differences in ambient sound levels, etc. Examples herein may measure the user preference volume based on their perceived output volume and then may attempt to make the user experience more uniform across device types. This may include when the device is equipped with a distance sensor to adjust the volume based on the user's distance to the audio output device, such as to maintain a volume level at the user's position as the user moves around a room. In this way, some examples may attempt to make several different audio output devices with different capabilities sound similar in volume to the user. In some examples, the user's preferences may be learned and stored to recall preferences or historical preferences for different environments.

In some examples, the volumes of different audio output devices are adjusted so that if a user moves from home audio to car audio, then the user may not experience a large volume differential in how they were listening.

When using audio output devices, users tend to set volume preferences on whatever system they are using. However, in modern home environments, users tend to have single sources (such as their phone) for audio that may push audio to different devices. In an environment like this, users may switch location and speakers frequently, but because capabilities are different among speaker systems users may have a frustrating experience when changing listening environments. In some examples, an electronic device may measure and interpret the environment and the user preference for that environment. Then with this information, the electronic device may read capabilities of the audio output device being switched to and attempt to compensate the output audio volume to match the user's perception of loudness. In this way, users may have an experience that is similar in perceived volume across different connected speakers.

In some examples, this may be accomplished by evaluating several factors of the environment. The device may measure the overall ambient level of the room, and the user position in the room relative to the speakers of interest.

In some examples, a learning mode may prompt a user to confirm if they can comfortably hear the current audio output from the device. Once the user responds yes, then there may be a reoccurring method of evaluation of user position in the room and ambient noise level. In some examples, as the user position changes in relation to the output speaker, then the audio may automatically change output volume to maintain the relative sound output level. Additionally, as the environment ambient volume level changes then the output volume of the speaker may raise and lower to maintain the relative perceived output volume. In some examples, using these two measurement points, as the user moves around the room and the ambient environment changes the overall decibel (dB) level of the audio output may adjust to make the transmitted sound similar in dB level to where the user is in the environment.

As the user moves between speaker output devices, such as switching from a surround sound system to a headset, then the audio source device may use the relative dB level from the previous speaker and compensate it to be relatively similar sounding in the person's ear. For example, if the dB level of a speaker in a surround system is relatively lower to fill a room, then when switching to a headset, the head-related transfer function (HRTF) may be compensated to simulate the relative sound that was perceived while the user was using the previous speaker system. In this way, simulated surround sound on a headset device may sound like the user standing at the specific position in the room from the previous system.

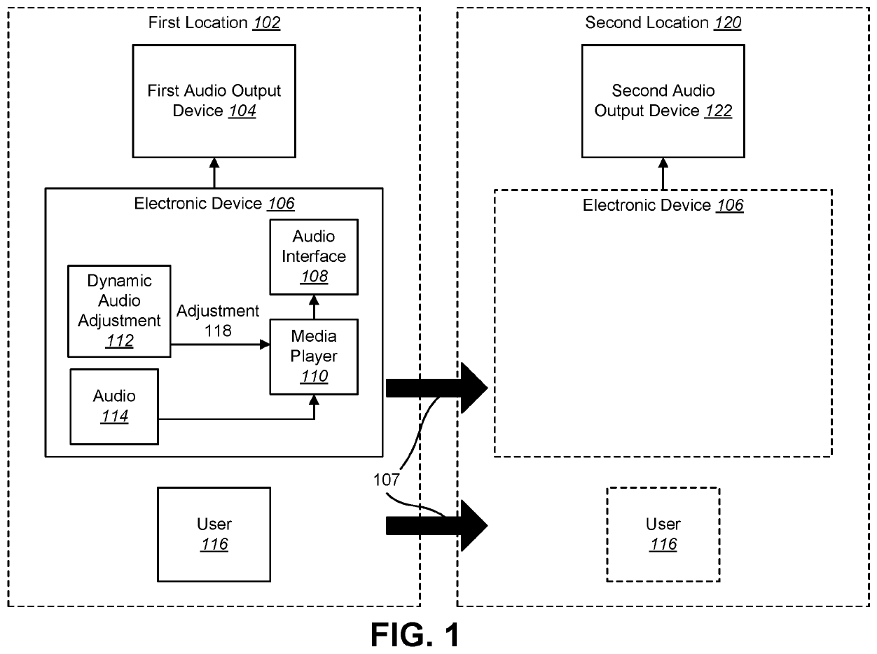

FIG. 1 is a block diagram of an example of an electronic device 106 that may automatically adjust the volume of audio 114 being played as it moves from a first audio output device 104 to a second audio output device 122.

A user 116 listens to audio 114 being played from a source electronic device 106 to the first audio output device 104. An electronic device is a device that includes electronic circuitry (e.g., integrated circuitry, a chip(s), etc.). Examples of electronic devices may include computing devices, smartphones, tablet devices, game consoles, etc. Some examples of electronic devices may utilize circuitry (e.g., controller(s) and/or processor(s), etc.) to perform an operation or operations. In some examples, electronic devices may execute instructions stored in memory to perform the operation(s). Instructions may be code and/or programming that specifies functionality or operation of the circuitry. In some examples, instructions may be stored in memory (e.g., Read-Only Memory (ROM), Erasable Programmable Read-Only Memory (EPROM), Electrically Erasable Programmable Read-Only Memory (EEPROM), flash memory, dynamic random access memory (DRAM), synchronous DRAM (SDRAM), magnetoresistive random-access memory (MRAM), phase-change random-access memory (PCRAM), hard disk drive (HDD), solid state drive (SSD), optical drive, etc.). In some examples, different circuitries in an electronic device may store and/or utilize separate instructions for operation.

In some examples, an electronic device may be linked to another electronic device or devices using a wired link. For example, an electronic device (e.g., display device, monitor, television, etc.) may include a wired communication interface (e.g., connector or connectors) for connecting electronic devices. Connectors are structures that enable forming a physical and/or electrical connection. For instance, a connector may be a port, plug, and/or electrical interface, etc. A connector or connectors may allow electronic devices to be connected with a cable or cables. Examples of connectors include DisplayPort™ (DP) connectors, High-Definition Multimedia Interface (HDMI®) connectors, Universal Serial Bus (USB) connectors, Lightning® connectors, Digital Visual Interface (DVI) connectors, OCuLink connectors, Ethernet connectors, etc.

In some examples, an electronic device 106 may be linked to an audio output device 104 with a wireless link. For instance, an electronic device 106 (e.g., display device, monitor, television, etc.) may include a wireless communication interface 108 to send and/or receive wireless (e.g., radio frequency (RF)) signals. Examples of wireless communication interfaces 108 may include an Institute of Electrical and Electronics Engineers (IEEE) 802.11 (Wi-Fi) interfaces, Bluetooth interfaces, cellular (e.g., 3G, Long-Term Evolution (LTE), 4G, 5G, etc.) interfaces, etc. In some examples, the wireless communication interface 108 may be referred to as an audio interface 108.

A link between an electronic device 106 and an audio output device 104 may be a direct link (e.g., without an intervening device) or an indirect link (e.g., with an intervening device or devices). For instance, a link may be established between electronic devices over a network using a hub(s), repeater(s), splitter(s), router(s), and/or switch(es), etc.

In some examples, an audio output device 104 may be a speaker, a smart speaker, an audio receiver, a television, a monitor, etc. The audio output device 104 is an electronic device capable of producing audible sound.

In some examples, an electronic device 106 may be linked to an audio output device 104 to communicate an audio signal or to play audio. For instance, when the electronic devices are linked (e.g., wireless communication is set up between the electronic device and the audio output device), the electronic device may 106 follow a protocol or protocols to set up an audio link. An audio link is a communication channel for audio. For instance, an audio link may carry an audio stream. In some examples, the audio may be music, a podcast, an audiobook, etc. As used herein, a “source device” is an electronic device for sending audio and a “sink device” is an audio output device for receiving audio.

A media player 110 on the electronic device 106 plays the audio 114 on the first audio output device 104 by sending the audio 114 through the audio interface 108. In some examples, a media player 110 may be a set of instructions that, when executed, cause the electronic device 106 to play or stream different forms of multimedia, including audio 114, through the audio interface 108.

Dynamic audio adjustment instructions 112 cause, when executed, the electronic device 106 to monitor audio output information and cause an adjustment 118 to be made to the audio being played. In some examples the adjustment 118 may be a volume change.

In the example of FIG. 1, the electronic device 106 and the first audio output device 104 are located at a first location 102. The user 116 with the electronic device 106 then moves 107 to a second location 120. When the electronic device 106 moves 107 from the first location 102 to the second location 120 it may disconnect from the first audio output device 104 and may connect to the second audio output device 122. In some examples, the dynamic audio adjustment instructions 112 may cause, when executed, automatic adjustment to the audio 114 being played without input from the user 116.

When the electronic device 106 connects to the second audio output device 122 the dynamic audio adjustment instructions 112 may cause, when executed, automatic adjustment to the audio 114 being played so that the perceived loudness to a user 116 is similar in the second location 120 as the perceived loudness was in the first location 102. For example, assume that the first location 102 is quiet and at the first location 102 the electronic device 106 is playing the audio 114 at 25% of the maximum volume. Next, assume that the second location 120 is a noisy environment. In order for the user 116 to have a similar perceived loudness of the audio at the second location 120 as the first location 102, the electronic device 106 may increase the volume of the audio 114 being played through the media player 110 on the second audio output device 122.

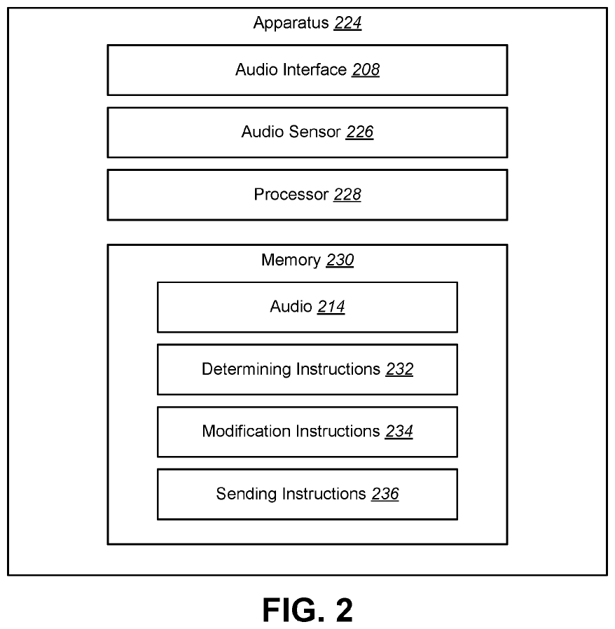

FIG. 2 is a block diagram of an example of an apparatus 224 that may determine an audio adjustment based on the ambient sound level. The apparatus 224 may include an audio interface 208 to send the audio 214 to an audio output device. The apparatus 224 may include an audio sensor 226 to detect an ambient sound level. The apparatus 224 may also include a processor 228 to execute instructions stored in the memory 230.

The memory 230 may store the audio 214 to be played. The memory 230 may also store instructions to be executed by the processor 228. Determining instructions 232 cause, when executed by a processor resource, determination of an audio adjustment based on the ambient sound level. Modification instructions 234 cause, when executed, modification of an output parameter based on the audio adjustment. The output parameter may be a setting or settings used by the media player 110. Sending instructions 236 cause, when executed, sending of the audio 214 to the audio output device.

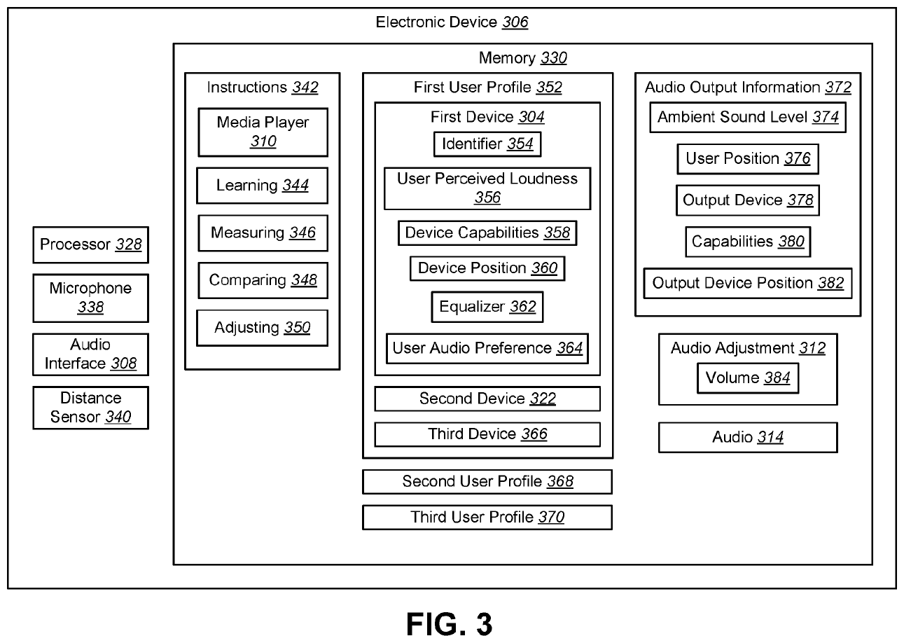

FIG. 3 is a block diagram of an example of an electronic device 306 that may determine an audio adjustment 312 based on the ambient sound level 374. The electronic device 306 may include a processor 328 for executing instructions 342 from the memory 330. A microphone 338 may be used to measure 346 the ambient sound level 374 where the electronic device 306 is located. An audio interface 308 may send audio 314 to audio output devices.

The electronic device 306 may include a distance sensor 340 to sense the distance between a user 116 and the audio output device 104. In some examples a distance sensor 340 may include a camera to measure the user position or distance. The device may also use user presence detection. For example, the device may send out audio, ultrasonic waves or an infrared pulse to determine the location of the user. In some examples, to find a user position 376 the electronic device 306 or audio output device 104 may use time of flight sensors, light-based reflection sensors, IR based webcams, eye trackers, etc. The user position 376, after being determined, is stored as part of the audio output information 372.

In some examples, an integrated security system with facial recognition may be used to trigger a smart home system to begin playing music and even track the user to have the music follow them from room to room. The audio output device 104 may identify the user 116 using optical or other visual sensors to detect and identify the user 116 to apply user preferences 364.

The memory 330 may include instructions 342 to be executed by the processor 328. Media player instructions 310 may include the instructions to cause, when executed, the electronic device 306 to play the audio 314.

Learning instructions 344 may cause, when executed, training of the device to play the desired perceived loudness 356 for a user 116. When in learning or training mode, the device may play the audio 314 on the current audio output device 378. The device may then measure the overall ambient sound level 374 of the room 102 or location 102. The device may then determine the user position 376 in the room relative to the speakers or the current audio output device 378. The device 306 may then prompt to user 116 to confirm if they can comfortably hear the current audio output from the device 306. Once the user 116 responds yes, then there may be a reoccurring method of evaluation of user position 376 in the room 102 and ambient sound level 374. As the position changes in relation to the output speaker, then the device 306 may automatically change output volume to maintain the relative sound output level. Additionally, as the environment ambient sound level 374 changes then the output volume of the speaker 104 may raise and lower to maintain the relative perceived output volume. If the user 116 responds no, then settings at the media player 310, such as volume, may be adjusted and then training or learning cycle may be repeated until the user 116 is satisfied with the audio experience.

Measuring instructions 346 cause, when executed, measuring of the ambient sound level 374 through use of the microphone 338. In some examples, the electronic device 306 may include a plurality of microphones 338 and the measuring instructions 346 may access more than one microphone 338 to measure the ambient sound level 374. In one example, the measurement of the ambient sound level 374 is in dB. In another example, the measurement of the ambient sound level 374 may be measured as sound intensity in W/m (i.e., watts per meter distance).

Comparing instructions 348 may cause, when executed, comparison of the current measurements of the audio output information 372 with information from the user profiles 352 to determine if an audio adjustment 312 should be made. Adjusting instructions 350 cause, when executed, an audio adjustment 312 to be provided to modify the audio output.

In one example, the user perceived loudness 356 may be a measurement in dB. The comparing instructions 348 may cause, when executed, a comparison of the user perceived loudness 356 with the ambient sound level 375 to determine if an audio adjustment 312 should be made. In addition, the comparing instructions 348 may cause, when executed, a comparison of the device capabilities 358 with the capabilities 380, as well as the device position 360 with the output device position 382. In this way the comparing instructions may take into account the state of the room or location as well as the type of audio output device 104.

In some examples, if a user noted previously they were uncomfortable at a certain volume intensity level, then the instructions 342 may cause, when executed, the volume 384 to be lowered through a downward audio adjustment 312. After this adjustment, the ambient noise floor (previously recorded by the system per user feedback) may be compared to the current noise floor. If there is a significant difference, there may be an audio adjustment 312 upwards to increase the sound output.

The memory 330 may store a first user profile 352. The first user profile 352 may store information about a first device 304. The first device 304 is one of the audio output devices 104 that the first user has used with the electronic device 306. The first device 304 information may include a first device identification 354 to identify the device. In one example a first device identification 354 may be a device name or MAC Address.

User perceived loudness 356 may indicate the user's past loudness experience or history on the first device 304. In some examples, the user perceived loudness 356 is the user's audio preference 364 taking into account the audio output information 372 for a specific room or environment.

The user's audio preference 364 may include information about the user's 116 past historical audio settings without taking into account the audio output information 372. The audio preference 364 may include equalizer preferences. For example, one user may be more sensitive to bass versus treble. Including equalizer preferences with the user audio preference 364 may be used for such users. In some examples, the perceived loudness 356 may be based on the ambient noise 374, user feedback on the output level, and the speaker sound output.

In one example, the user audio preference 364 may be a most recent audio setting when the connection is established within a time threshold. If a user 116 moves to a new location within a certain number of minutes, for example, the user audio preference 364 may be the most recent volume setting.

In one example, the user perceived loudness 356 may be a certain dB level as measured at the electronic device 306. By comparing the user perceived loudness 356 and the user's audio preference 364, an audio adjustment 312 may be determined to change the audio output to be closer to the desired dB level as found in the user's audio preference 364.

Device capabilities 358 may indicate what abilities the first device 304 has. In some examples, device capabilities 358 may include how many speakers the device has, the power rating of the speakers, whether the device 304 is mono, stereo, Dolby® digital, etc.

A device position 360 may indicate the position of the first device 304 in a particular location 102. The first device 304 information may also include an equalizer 362 to be used in filtering audio to achieve the user perceived loudness 356. In one example, an equalizer may include certain dB amplitudes at certain frequency peaks. By adjusting an equalizer, the individual peaks are adjusted when signals are combined. An overall amplitude adjustment across the whole spectrum may affect the loudness of the sound. An equalizer may adjust with a more complex waveform to more finely tune to the user preference for signal frequency (e.g., one user may prefer more bass versus treble).

The first user profile 352 may also include second device 322 information about a second audio output device 122. This second device 322 information may include data similar to the information stored in the first device 304 information. The first user profile 352 may also include a third device 366 information to store information about a third audio output device. The information 366 regarding the third audio output device may be similar to the information stored for the first device 304 information. The memory 330 may store a second user profile 368 and a third user profile 370. The second user profile 368 and the third user profile 370 may store information similar to the information that is stored for the first user profile 352.

The memory 330 may store audio output information 372. The audio output information 372 may include information about the current audio output device 104 or the current location 102. This audio output information 372 may be used by the comparing instructions 348 and adjusting instructions 350 to cause, when executed, adjustments to be provided to the media player 310 in order to achieve the desired perceived loudness for a user. The audio output information 372 may include an ambient sound level 374. The audio output information 372 may include a user position 376. The user position 376 may be determined as described above. The audio output information 372 may include output device capabilities 380. The output device capabilities 380 may be retrieved from the user profile 352 data when the audio output device is identified. Output device position 382 may be stored as part of the audio output information 372.

The memory 330 may store an audio adjustment 312 to modify or change a setting of the media player 310. In an example, the audio adjustment 312 may be a volume 384.

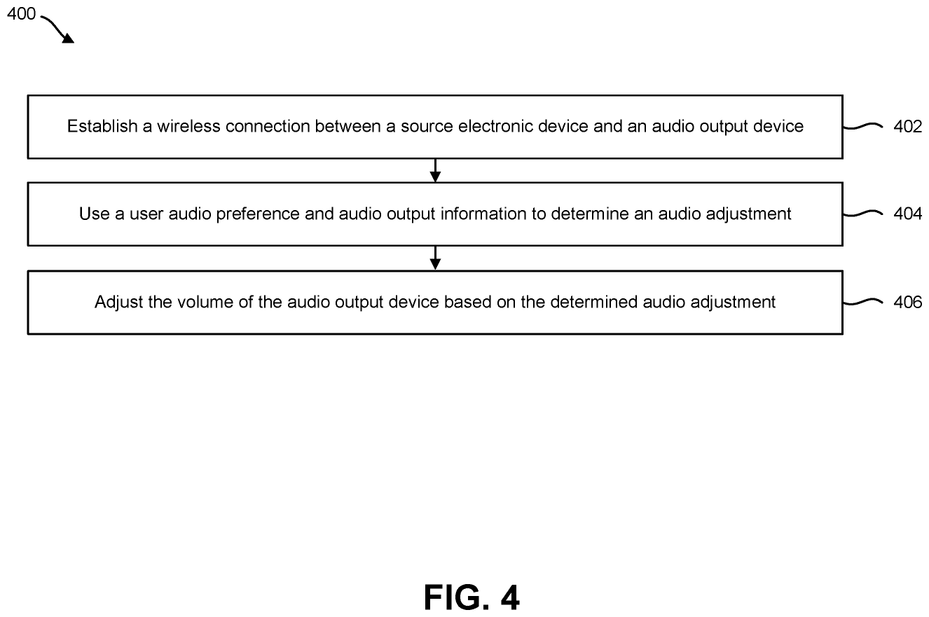

FIG. 4 is a flow diagram illustrating an example of a method 400 for electronic device audio adjustment. The method 400 and/or a method 400 element(s) may be performed by an electronic device 106. A wireless connection may be established 402 between a source electronic device 106 and an audio output device 104. A user audio preference and audio output information may be used 404 to determine an audio adjustment 118. A volume of the audio output device 104 may be adjusted 406 based on the determined audio adjustment.

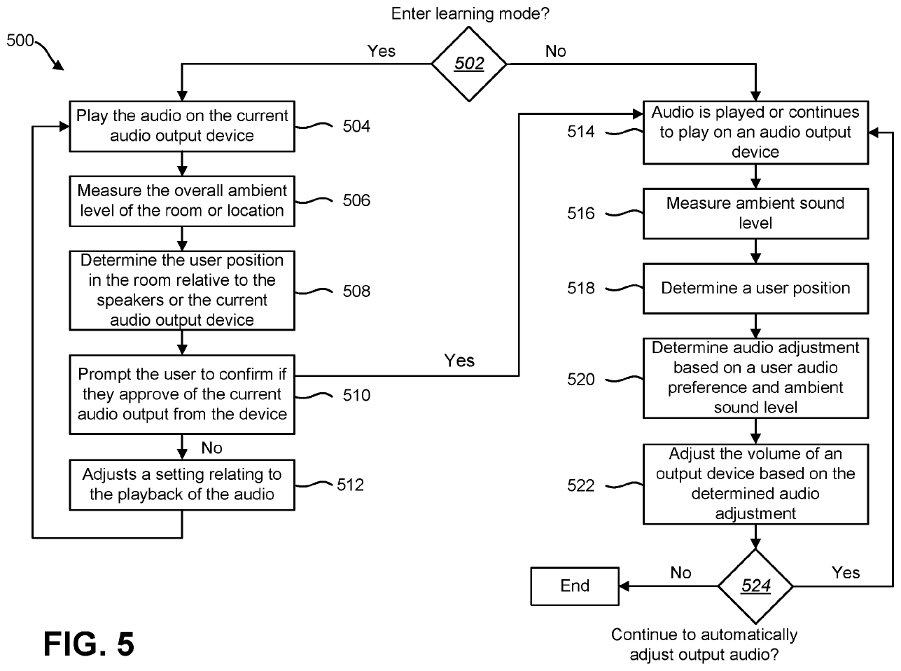

FIG. 5 is a flow diagram illustrating an example of a method 500 for electronic device audio adjustment. The method 500 and/or a method 500 element(s) may be performed by an electronic device.

At 502, it is determined whether the device should enter learning mode. In some examples, a parameter may indicate whether learning mode should be entered. This parameter may be set by a user 116 or it may be set by other instructions stored in the electronic device 106. When in learning or training mode, the device 106 may play 504 the audio on the current audio output device 104. The device 106 may then measure 506 the overall ambient level of the room or location 102. The device 106 may then determine 508 the user position in the room relative to the speakers or the current audio output device 104. The device 106 may then prompt 510 the user 116 to confirm if they approve of the current audio output from the device. If the user 116 responds yes, the method 500 continues as shown to 514. If the user 116 responds no, the method 500 adjusts 512 a setting relating to the playback of the audio. In some examples, the setting may be a volume, a bass booster, a loudness setting, etc. The method 500 then returns to 504.

At 514, audio is played or continues to play on an audio output device 104. An ambient sound level is measured 516. In some examples, a user position may be determined 518. An audio adjustment is determined 520 based on a user audio preference and the ambient sound level. In one example, if the user 116 has been in a location already and the method 500 has been operating in a continual manner, if the user position has not changed or the ambient sound level has not changed, it may be determined that no audio adjustment should be made.

The volume of an audio output device 104 is adjusted 522 based on the determined audio adjustment. At 524, the method determines whether to return to 514 to continue automatically adjusting the output audio. If the method continues, control returns to 514.

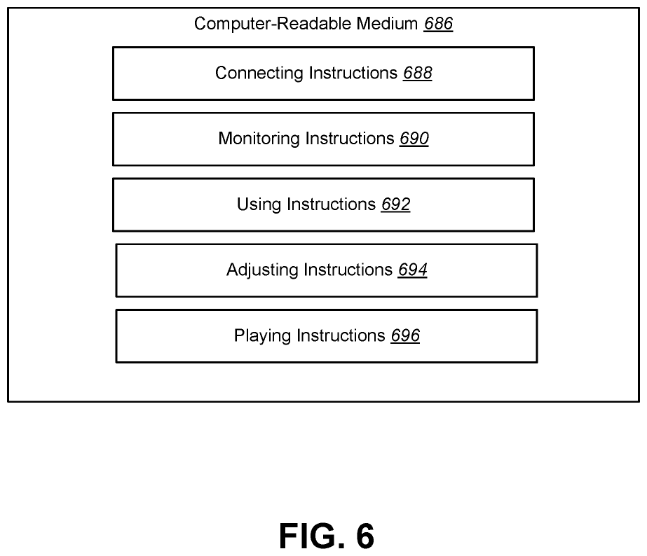

FIG. 6 is a block diagram illustrating an example of a computer-readable medium 686 for electronic device audio adjustment. The computer-readable medium 686 may be a non-transitory, tangible computer-readable medium. The computer-readable medium 686 may be, for example, RAM, EEPROM, a storage device, an optical disc, and/or the like. In some examples, the computer-readable medium 686 may be volatile and/or non-volatile memory, such as DRAM, EEPROM, MRAM, PCRAM, memristor, flash memory, and/or the like. In some examples, the computer-readable medium 686 may be included in an electronic device and/or may be accessible to a processor of an electronic device. In some examples, the computer-readable medium 686 may be an example of the memory described in relation to FIGS. 2 and 3.

The computer-readable medium 686 may include code (e.g., data, executable instructions, and/or executable code). For example, the computer-readable medium 686 may include connecting instructions 688, monitoring instructions 690, using instructions 692, adjusting instructions 694, and playing instructions 696.

The connecting instructions 688 may be instructions that when executed cause a processor to establish a connection with an audio output device 104. The monitoring instructions 690 may cause, when executed, the processor to monitor or measure the ambient sound level at the electronic device 106. The using instructions 692 when executed may cause the processor to determine an audio adjustment 118 using user audio preferences and the ambient sound level. In some examples, the adjusting instructions 694 may cause, when executed, an adjustment to a volume of the audio output device 104 based on the determined audio adjustment. The playing instructions 696 may cause, when executed, the processor to play the audio on the audio output device 104. The playing instructions 696 may be part of the media player 110.

A technique or techniques, a method or methods (e.g., method(s) 400 and/or 500) and/or an operation or operations described herein may be performed by (and/or on) an electronic device, a source electronic device, and/or an audio output device. In some examples, an electronic device and/or an audio output device may include circuitry (e.g., a processor with instructions and/or connection interface circuitry) to perform a technique or techniques described herein.

As used herein, the term “and/or” may mean an item or items. For example, the phrase “A, B, and/or C” may mean any of: A (without B and C), B (without A and C), C (without A and B), A and B (but not C), B and C (but not A), A and C (but not B), or all of A, B, and C.

While various examples are described herein, the disclosure is not limited to the examples. Variations of the examples described herein may be within the scope of the disclosure. For example, aspects or elements of the examples described herein may be omitted or combined.

1. A method, comprising:
establishing a wireless connection between a source electronic device and an audio output device;
using a user audio preference and audio output information to determine an audio adjustment; and
adjusting a volume of the audio output device based on the determined audio adjustment.

2. The method of claim 1, wherein the audio output device comprises a speaker.

3. The method of claim 1, wherein the audio output information comprises an ambient sound level.

4. The method of claim 3, wherein the audio output information further comprises audio output device capabilities.

5. The method of claim 1, wherein the audio output information comprises a position of a user relative to the audio output device.

6. The method of claim 1, further comprising learning the user audio preference by providing a prompt on the source electronic device.

7. The method of claim 1, wherein the volume is adjusted automatically when the connection is established between the source electronic device and the audio output device.

8. The method of claim 1, wherein the user audio preference is a most recent audio setting when the connection is established within a time threshold.

9. An apparatus, comprising:
an audio interface to send audio to a speaker;
an audio sensor to detect an ambient sound level; and
a processor to:
determine an audio adjustment based on the ambient sound level; and
modify an output parameter based on the audio adjustment; and
send the audio to the speaker.

10. The apparatus of claim 9, wherein the processor is to further determine the audio adjustment based on a most recent audio setting when a connection to the speaker is established within a time threshold.

11. The apparatus of claim 9, wherein the processor is to further determine the audio adjustment based on a user audio preference.

12. The apparatus of claim 9, wherein the processor is to determine a change in the ambient sound level and is to determine a new audio adjustment when the change is determined.

13. A non-transitory tangible computer-readable medium comprising instructions when executed cause a processor to:
connect to an audio output device;
monitor an ambient sound level;
use a user audio preference and the ambient sound level to determine an audio adjustment;
adjust a volume of an audio output device based on the determined audio adjustment; and
play audio on the audio output device.

14. The non-transitory tangible computer-readable medium of claim 13, wherein the processor is to determine a position of a user relative to the audio output device and is to use the position in determining the audio adjustment.

15. The non-transitory tangible computer-readable medium of claim 13, wherein the processor is to learn a new user audio preference when a new audio output device is connected.
